(19) United States
(12) Patent Application Publication
(10) Pub. No.: US 2015/0206740 A1
(43) Pub. Date: Jul. 23, 2015

(54) ELECTRICAL CHARGE REGULATION FOR A SEMICONDUCTOR SUBSTRATE DURING CHARGED PARTICLE BEAM PROCESSING

(71) Applicant: MAPPER LITHOGRAPHY IP B.V, Delft (NL)

(72) Inventor: Pieter Lucas BRANDT, Rotterdam (NL)

(21) Appl. No.: 14/602,318

(22) Filed: Jan. 22, 2015

Related U.S. Application Data
(60) Provisional application No. 61/930,345, filed on Jan. 22, 2014.
(60) Provisional application No. 61/969,322, filed on Mar. 24, 2014.

(51) Int. Cl. H01L 21/027; H01J 37/02; H01J 37/317; H01L 21/3205; H01L 23/48

(52) U.S. Cl. CPC H01L 21/0277; H01L 21/32051; H01L 23/48; H01J 37/3174; H01J 37/026

(57) ABSTRACT

A method for preparing a semiconductor target (10), the method comprising providing a semiconductor substrate (12) including a main substrate surface (14) which defines a substrate periphery (20) along an outer edge. The semiconductor substrate (12) further has an structure layer (30) arranged on the main substrate surface, and comprising a structure layer periphery (32) that is located inwards with respect to the substrate periphery, so as to leave exposed a peripheral substrate region (22) along the substrate periphery. The method further comprises applying an electrically conductive layer (38) on the structure layer, wherein the electrically conductive layer extends beyond the structure layer periphery to establish electrical contact in a contacting portion (23) of the peripheral substrate region.

### BACKGROUND ART

Charged particle lithography machines and inspection machines are used to expose patterns onto semiconductor targets (e.g. silicon wafers), typically as part of a semiconductor device manufacturing process. In a lithography system, a wafer is usually exposed at multiple locations by particle beams (e.g. electron beams) that are generated by a beam generator column (e.g. electron optical column) in the lithography system. Typically, the wafer is positioned on a wafer table and the exposure of the wafer involves controlled displacement of the wafer table with respect to the beam generator column.

International patent application WO2009/106560 discloses a charged particle lithography system, wherein a final lens element of a projection column may be kept at a same electric potential as the target (or at least at a similar electric potential with only a relatively small potential difference within a predetermined budget), to avoid creation of a strong electric field between the final lens element and the target, which would otherwise disrupt the desired charged particle beam trajectories.

During charged particle beam exposure of a target, at least an upper layer of the target undesirably becomes electrically charged as a result of the charged particles impinging on the target. The accumulated electrical charge locally creates undesirable electric fields between the target and surrounding components, and in particular with respect to a lower side of the particle beam generator which directly faces the exposed surface of the target. Such local electric field disturbances undesirably alter the projection direction of the charged particle beams as well as the achievable degree of beam focus at the target.

US 2006/0228897 A1 discloses a method for heat treating a semiconductor wafer in a process chamber, as an intermediate part of an overall multi-step technique for processing the wafer. An energy transfer layer is applied to at least a portion of the wafer, which serves to transfer thermal energy, for example by absorbing emitted thermal energy from an energy source. The energy transfer layer is used temporarily and is removed at least sufficiently for subjecting the wafer to a subsequent step in the multi-step processing of the wafer. An energy transfer layer is disclosed formed from metals, metal alloys and other electrically conducting materials. According to US 2006/0228897 A1 these metallic materials often exhibit high thermal absorption coefficients over a wide range of wavelengths. Furthermore, these materials exhibit high melting points, which may be useful for thermal processing. Many metals are also generally good reflectors of radiation, which affects the heat energy transfer in the energy transfer layer. US 2006/0228897 A1 is not related to the effects of electrical fields and does not disclose measures for regulating undesired accumulation of electrical charges on wafers.

In JP S6074616 A a conductive pin is disclosed capable of breaking through an oxide film formed on a substrate, thereby enabling charges stored in the substrate to be grounded via the conductive pin. In a process of charged particle beam exposure of a semiconductor target, use of such pin is undesirable as it damages one or more layers on the substrate. JP S6074616 A further discloses a pin that is brought into contact with a conductive side wall of a substrate using spring force, thereby grounding the side wall via the pin. It is not apparent how this pin can be used for preventing an upper layer of a semiconductor target becoming electrically charged as a result of charged particles impinging the target during charged particle beam exposure of the target.

In charged particle systems wherein the available space between the electron optical column and the target is limited, it is not a straightforward task to implement effective measures for regulating undesired accumulation of electrical charge on the target.

### SUMMARY

It would be desirable to provide a semiconductor target and processing system wherein the layout of various components assists in preventing or reducing the generation of undesired electric fields between the target and the processing system.

Therefore, according to a first aspect of the invention, there is provided a semiconductor target, comprising: —a semiconductor substrate, including a main substrate surface which defines a substrate periphery along an outer edge; —a structure layer arranged on the main substrate surface, and comprising a structure layer periphery that is located inwards with respect to the substrate periphery so as to define a peripheral substrate region along the substrate periphery which is not covered by the structure layer; wherein the semiconductor target further comprises: —an electrically conductive layer formed on the structure layer, and extending beyond the structure layer periphery to establish electrical contact in a contacting portion of the peripheral substrate region.

By the abovementioned measures, an electrically conductive path through the conductive layer of the target and towards the peripheral substrate region is established, which allows net electrical charge received by the main target surface during charged particle beam processing to be laterally conveyed towards the outer edge of the semiconductor substrate. This target layer arrangement enables various lithography system implementations including one or several contacting structures that are adapted for engaging a lateral target surface, in a manner that allows convenient dissipation of received net electrical charge via the electrically conductive layer, the substrate edge, and the contacting structure. Such charge dissipation implementations are particularly useful in lithography systems wherein a distance between the target and a proximal end of a charged particle beam generator column is relatively small (e.g. in the order of 100 micrometers or even less), and wherein obstruction of the column by a contacting structure during relative movement between column and target is to be avoided. By immediate lateral dissipation of net charge away from the target and towards a remote drain (e.g. ground), the creation of undesired electric fields between the target and the processing system can be conveniently prevented or at least reduced.

According to a second aspect of the invention, and in accordance with the advantages and effects described herein above, there is provided a method for preparing a semiconductor target, wherein the method comprises: —providing a semiconductor substrate including: —a main substrate surface which defines a substrate periphery along an outer edge; and—a structure layer arranged on the main substrate surface, and having a structure layer periphery that is located inwards with respect to the substrate periphery, so as to define a peripheral substrate region along the substrate periphery which is not covered by the structure layer; wherein the method further comprises: —applying an electrically conductive layer onto the semiconductor substrate and the structure layer, wherein the electrically conductive layer extends beyond the structure layer periphery to establish electrical contact with a contacting portion of the peripheral substrate region.

The method for preparing the semiconductor target for charged particle beam exposure may involve various manufacturing steps, among which are steps for applying various layers onto the target (e.g. insulating layers, the abovementioned electrically conductive layer, and a resist layer). Furthermore, the preparation method may involve various steps for priming the target for actual charged particle beam exposure, among which are steps for positioning the target onto a target receptor of a lithography system, and steps for engaging the lateral target surface with a cutting edge of a contacting structure, in order to establish an electrical path between the target's electrically conductive layer and an electric charge regulation control facility that is connected to the contacting structure.

### BRIEF DESCRIPTION OF THE DRAWINGS

Embodiments will now be described, by way of example only, with reference to the accompanying schematic drawings in which corresponding reference symbols indicate corresponding parts, and in which:

FIG. 1a schematically shows a charged particle lithography system according to an embodiment;

FIG. 1b schematically shows a perspective view of a semiconductor target in electrical contact with a contacting structure of a lithography system according to embodiments;

FIG. 2 schematically shows a top view of a semiconductor target in electrical contact with a contacting structure of a lithography system according to embodiments;

FIG. 3 schematically shows a side cross-sectional view of a semiconductor target according to an embodiment;

FIG. 4 schematically shows a side cross-sectional view of a semiconductor target according to an alternative embodiment;

FIG. 5 schematically shows a side cross-sectional view of a semiconductor target according to yet an alternative embodiment, and

FIG. 6 schematically shows a side cross-sectional view of a semiconductor target according to yet another embodiment.

The figures are meant for illustrative purposes only, and do not serve as restriction of the scope or the protection as laid down by the claims.

### DESCRIPTION OF ILLUSTRATIVE EMBODIMENTS

The following is a description of certain embodiments of the invention, given by way of example only and with reference to the drawings. Cylindrical coordinates are used herein to explain spatial characteristics of particular embodiments of the semiconductor target. The axis defined through a center of a predominantly circularly shaped target is referred to as “axial direction” Z. The “radial direction” R corresponds to any direction that points radially away from the axial direction Z and lies in a transversal plane for which the axial direction is a surface normal vector. The “angular direction θ” points along the (infinitesimal) angle of rotation of the radial position in the transversal plane. It should be understood that the directional definitions and preferred orientations presented herein merely serve to elucidate geometrical relations for specific embodiments, and should not be considered a limitation to the general concepts of the invention. For example, it may be possible to employ a semiconductor target with a rectangular shape, so that Cartesian coordinates would be preferable over cylindrical coordinates to describe geometric properties. Similarly, the terms “upper”, “lower”, “lateral”, etc. relate to a common horizontal orientation of a semiconductor target during processing, but may change in the case of target processing methods that involve different orientations for target and/or lithography system.

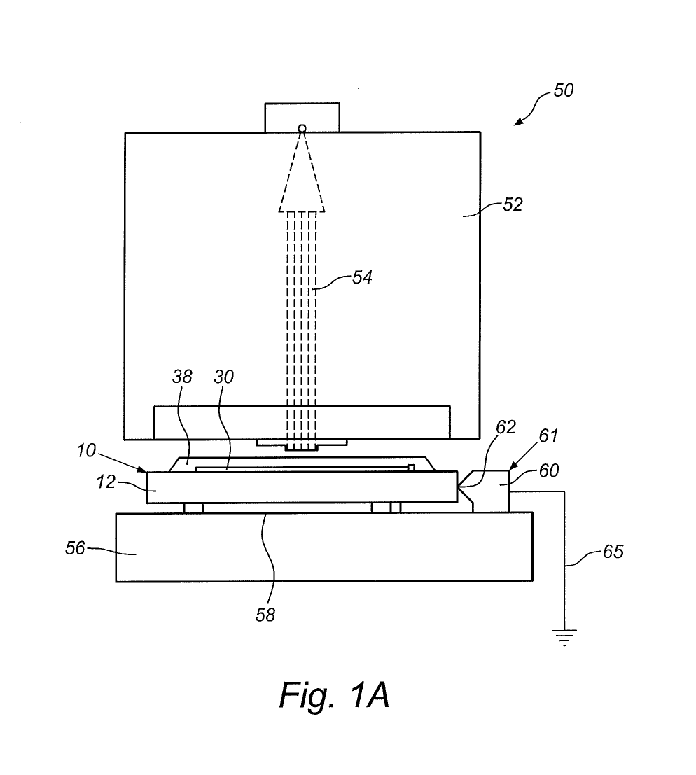

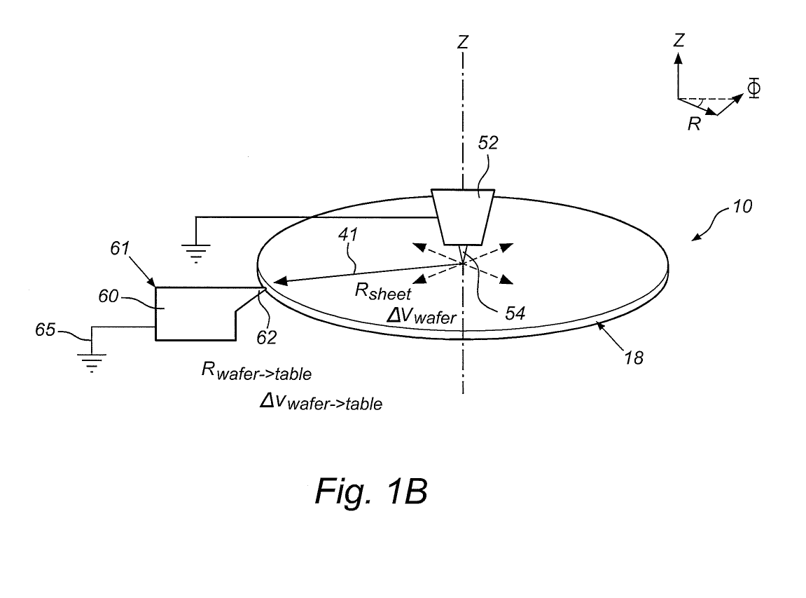

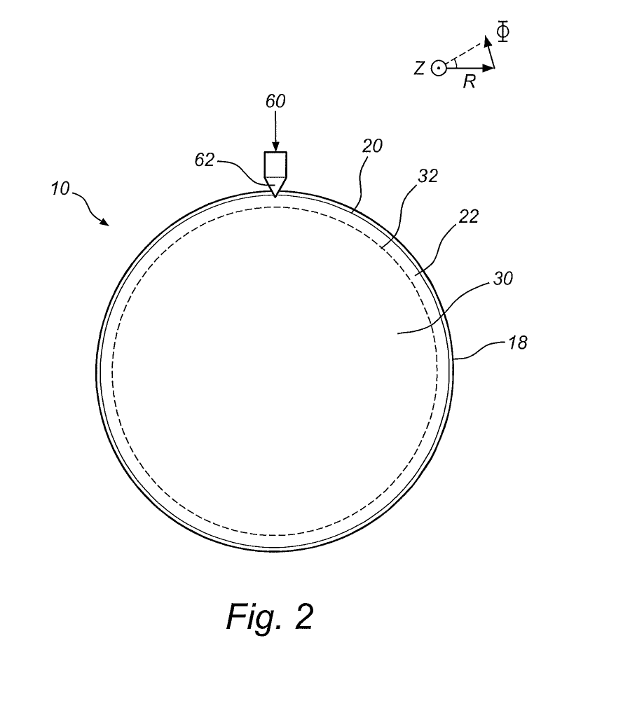

FIG. 1a schematically depicts a lithography system 50 according to an embodiment of the invention. In general, the lithography system 50 comprises a housing (not shown) which accommodates a charged particle projector 52 (e.g. a charged particle beam projection column), which is configured for generating one or more charged particle beams 54. The particle beams 54 are projected towards a semiconductor target 10 that comprises a semiconductor substrate 12 and a structure layer 30. Embodiments of the semiconductor target 10 will be explained below with reference to FIGS. 2-6.

The lithography system 50 comprises a receptor 56 for supporting the semiconductor target 10 in a target support region 58. The receptor 56, for example a wafer table, is typically carried by a moveable wafer stage (not shown) that allows controlled movement of the semiconductor target 10 with respect to the charged particle projector 52 during processing. The target support region 58 comprises a support surface, which is adapted to support the semiconductor target 10 at a bottom surface 16 of the semiconductor substrate 12. The support surface is adapted to stabilize the orientation of the semiconductor target 10, and to provide a good thermal contact between the semiconductor substrate 12 and the target support region 58. For this purpose, a plurality of support protrusions and an intermediate thermally conductive fluid may be provided at the target support region 58.

The receptor 56 further comprises a target contacting structure 60 that includes a sharp edge 62, which is adapted for engaging a lateral surface 18 of the semiconductor substrate 12. This sharp edge 62 may for example be formed as a cutting edge. The cutting edge 62 is depicted in FIG. 1a as a sharp edge that linearly extends along the angular direction Φ. As a result, the cutting edge 62 is adapted to engage with the lateral substrate surface 18 along a line in the plane spanned by the substrate 12. The contacting structure 60 may for example comprise a body having a triangular or pentagonal cross section defined in an axial-radial plane (i.e. viewed along the angular direction Φ), with the cutting edge 62 corresponding with an apex of the triangular or pentagonal shape. In alternative embodiments, the cutting edge may be directed along any line in the plane spanned by the axial direction Z and the angular direction Φ (e.g. a vertically oriented edge, an angularly oriented edge, or a linear combination of these directions).

The sharp edge 62 comprises an electrically conductive material, and is adapted for establishing electrical contact with the lateral surface 18 of the semiconductor substrate 12. The edge 62 is sufficiently sharp to locally penetrate an oxidation layer that may be formed on the lateral substrate surface 18 (e.g. as a result of local oxidation of semiconductor material). This cutting property ensures that the electrical contact between the contacting structure 60 and the semiconductor substrate 12 is not unnecessarily deteriorated due to a possibly high electrical resistance of such an oxidation layer. Preferably, the cutting edge 62 protrudes in a predominantly lateral direction (i.e. radial direction in the case of a circular substrate). The lateral protruding property helps to avoid that the cutting edge 62 would exert a supporting (“normal”) or downward pressing force on the semiconductor substrate 12.

Preferably, a top surface 61 of the contacting structure 60 is located below an upper surface 43 of the semiconductor target 10 (main target surface), to avoid collisions with a lower surface of the charged particle beam projector 52.

FIG. 1a depicts an implementation for a charge dissipation path 65 between the contacting structure 60 and ground potential (any electrical resistance of the charge dissipation path 65 is assumed to be negligible here). The electrical contact with the lateral substrate surface 18 thus allows electrical grounding of the semiconductor target 10 during processing.

According to embodiments, the contacting structure 60 may be mechanically fixed to the receptor 56 and comprises an electrically conductive path between the sharp edge 62 and the receptor 56. The electrical resistance between the sharp edge 62 and the receptor 56 is sufficiently low to provide an electrically conductive path between the substrate 12 and the receptor 56, which allows net electrical charge received by the target 10 during processing to be immediately dissipated.

The lithography system 50 may be provided with multiple contacting structures 60, for example two contacting structures 60 that enclose the semiconductor target 10 from two opposite lateral sides.

In yet other embodiments, the contacting structure(s) 60 may be attached to (e.g. supported by or suspended from) other structures that may surround the target support region 58.

FIG. 1b schematically shows a perspective view of a semiconductor target 10 in electrical contact with a contacting structure 60 of a lithography system 50 according to embodiments. The contacting structure 60 enables an electrical connection between ground (see FIG. 1a) and a lateral surface 18 of the semiconductor target 10. This lateral connection establishes an electrically conductive path 41 for the electron currents caused by the charged particle beam(s) 54 emanating from the projector 52, from a region of beam impact on the semiconductor target 10 towards the contacting structure 60, and onwards to ground.

For example in a lithography system that is adapted for generating charged particle beams 54 with a total current in the order of 200 microamperes or lower, an electrical sheet resistance of the electrically conductive layer 38 preferably has a value below 10⁷ Ohms (this unit of sheet resistance is also indicated as “Ohms per square”) and probably even below 10⁵ Ohms, and an electrical resistance of the contacting structure 60 preferably has a value below 14 kilo Ohms.

FIG. 2 schematically shows a top view of an embodiment of a circular semiconductor target 10 which is in electrical contact with a contacting structure 60 of a lithography system (not shown). The semiconductor target 10 has a substrate with a lateral substrate surface 18 that defines a circular substrate periphery 20. A structure layer 30 is provided on top of the substrate, and comprises a circular structure layer periphery 32 that has a smaller radius that the substrate and which is located inwards with respect to the substrate periphery 20. As a result, a ring-shaped peripheral substrate region 22 is defined along the substrate periphery 20, which is not covered by the structure layer 30.

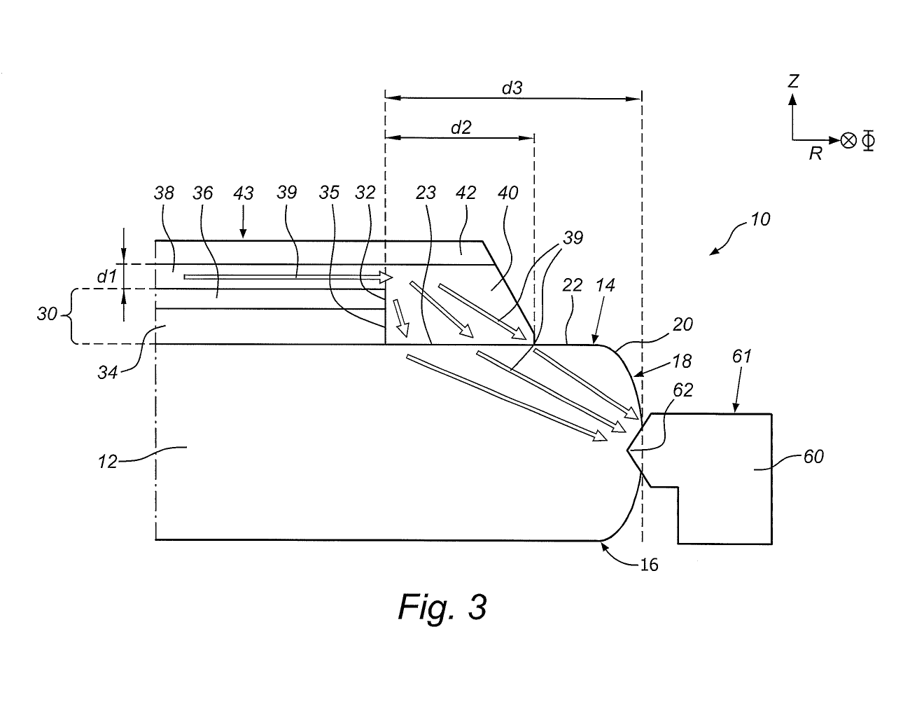

FIG. 3 schematically depicts a cross-sectional view of part of an embodiment of a semiconductor target 10, with a cross-section defined in a plane that is spanned by an axial direction Z and a radial direction R and intersecting the contacting structure 60. The semiconductor target 10 comprises a semiconductor substrate 12, which may be made of doped silicon. A typical maximum resistivity of the doped silicon is in the order of 100 to 1000 Ohms-centimeter. The semiconductor substrate 12 includes a main substrate surface 14 (upper substrate surface), a further substrate surface 16 (lower substrate surface) that is located opposite to the main surface 14, and a lateral substrate surface 18 that interconnects the main and further substrate surfaces 14, 16. The lateral substrate surface 18 defines a substrate periphery 20. A cross-section of the lateral substrate surface 18 traces out a curved and radially directed U-shape. In alternative embodiments, the U-shaped cross-section may trace out a polygonal or curved trajectory, or any intermediate form with (possibly slanted) straight portions and curved interconnecting portions.

The semiconductor substrate 12 forms a flat structure with transversal dimensions that are many orders of magnitude larger than a typical substrate thickness. The main and further (opposite) substrate surfaces 14, 16 typically extend in lateral directions along parallel planes.

A structure layer 30 is provided on top of the main substrate surface 14. This structure layer 30 may for example be formed by one or several device layers 34 which may comprise one or more electrically conducting layers, insulating layers, and/or semiconductor layers). In the embodiment shown in FIG. 2, the structure layer 30 comprises one device layer 34 with a cover layer 36 arranged on top of the device layer 34. The cover layer 36 may for example essentially consist of an electrically insulating material (e.g. a di-electric cover layer 36 essentially consisting of a material with a high electrical resistivity that exceeds 10¹² Ωm). The electrically conductive layer 38 is arranged on top of the cover layer 36. A resist layer 42 is provided on top of the electrically conductive layer 38.

The structure layer 30 (with initial layers 34, 36) may have been deposited on the semiconductor substrate 12 in prior processing steps and/or via other processing methods. The structure layer 30 may for example be an electronic semiconductor chip that has been formed on the wafer by an earlier semiconductor lithography process. The structure layer 30 comprises a structure layer periphery 32 that is located inwards with respect to the substrate periphery 20. As a result, a peripheral substrate region 22 is defined which is not covered by the structure layer 30 (i.e. is initially left exposed) along at least a part of the substrate periphery 20. In the embodiment shown in FIG. 3, the structure layer periphery 32 at least partially coincides with a device layer periphery 35 that marks the lateral perimeter of the device layer 34.

An electrically conductive layer 38, which may for example form a hard mask, is formed on top of the structure layer 30. The electrically conductive layer 38 extends beyond the structure layer periphery 32 of the structure layer 30 and forms a peripheral conduction portion 40 that is in electrical contact with the peripheral substrate region 22 along a contacting portion 23. In the embodiment of FIG. 3, the electrically conductive layer 38 extends downward beyond the structure layer periphery 32 and towards the peripheral substrate region 22, to form an electrical conduction path to the semiconductor substrate 12 along which electrical current(s) 39 may flow.

Net electrical charge that accumulates inside and/or on the surface of the top layer(s) of the semiconductor target 10 as a result of charged particle processing may be efficiently conducted through the electrically conductive layer 38, via the peripheral conduction portion 40 and the lateral contacting portion 23, through the peripheral substrate region 22, and into the semiconductor substrate 12.

In addition to the electron conduction properties of the electrically conductive layer 38, the combination of cover layer 36 and electrically conductive layer 38 may be optimized to minimize backscattering of incident electrons, to minimize (high energy) electron transfer into the device layers 34, and to optimize etch transfer of the exposed pattern in the resist layer 42 in which mechanical properties of the materials and their etch selectivity play a role.

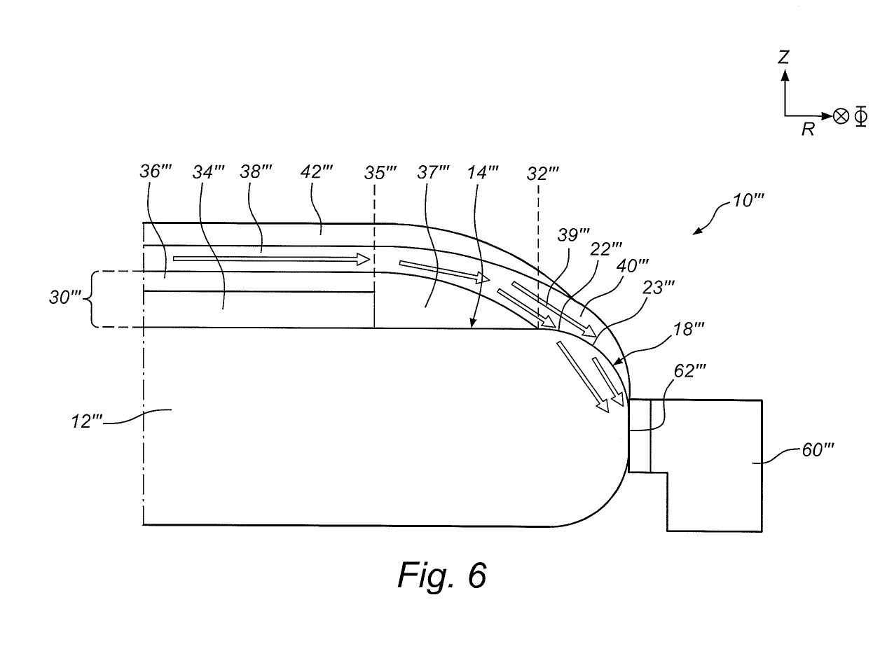

A width d2 spanned by the contacting portion 23 may extend up to a width d3 spanned by the peripheral substrate region 22. Typically, the lateral surface 18 of the semiconductor substrate 12 (i.e. the substrate periphery 20) may have a polygonal or curved cross-sectional profile, which limits the maximum extent of the contacting portion width d2 (This is not necessary though, as will become apparent from the embodiment explained with reference to FIG. 6). Preferably, the peripheral substrate region width d3 is in the order of one to several millimeters, although smaller values are possible. Correspondingly, the contacting portion width d2 may have a value that is similar to the peripheral substrate region width d3.

Preferably, the contacting portion width d2 is larger than a thickness d1 of the electrically conductive layer 38. For a typical conductive layer thickness d1 in the order of several tens of nanometers (e.g. 30 nanometers, or less), a ratio between d2 and d1 may be in the order of 10⁵ to 10⁶.

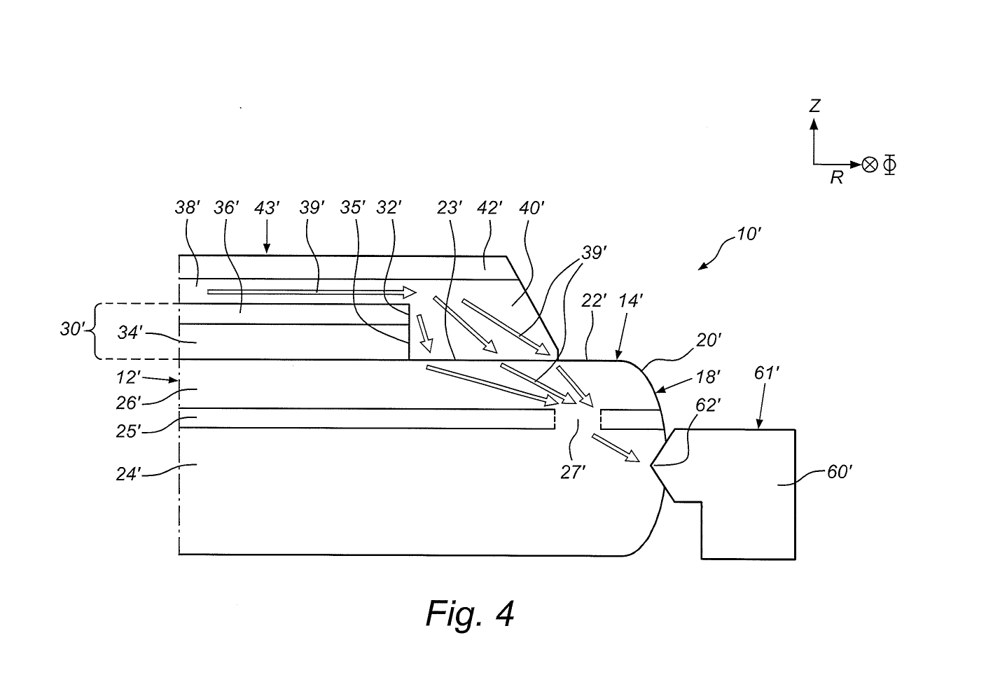

FIG. 4 shows an embodiment of a semiconductor target 10′, wherein the semiconductor substrate 12′ is formed by a so-called silicon on insulator (SOI) wafer. The majority of features in this embodiment are identical to the embodiment explained with reference to FIG. 2, and only the differences will be discussed.

The semiconductor substrate 12′ comprises a silicon base layer 24′, an insulating substrate layer 25′ arranged on top of the silicon base layer 24′, and a SOI layer 26′ arranged on top of the insulating substrate layer 25′. The insulating substrate layer 25′ is provided with an opening or cut-out 27′. This opening 27′ is filled with material having a sufficient electrical conductivity to establish electrical contact between the silicon base layer 24′ and the SOI layer 26′. The insulating substrate layer 25′ may for example be formed by a dielectric Silicon Oxide layer which is locally provided with the opening 27′ that is occupied by the doped Silicon material from which the base layer 24′ and the SOI layer 26′ are made. Because of this electrical connection between the base layer 24′ and the SOI layer 26′, an electrical contact between the substrate 10′ and the contacting structure 60′ may be established by engaging the sharp edge 62′ with a lateral surface portion of the base layer 24′.

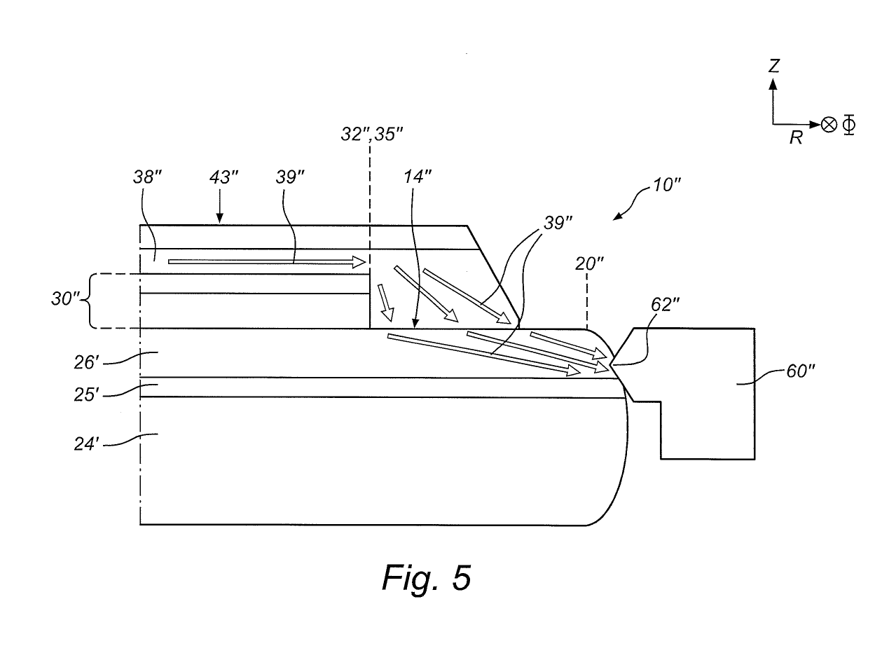

FIG. 5 shows an embodiment of a semiconductor target 10″, wherein the semiconductor substrate 12″ is also formed by a SOI wafer. The majority of features in this embodiment are identical to the embodiment explained with reference to FIG. 4, and only the differences are discussed.

In the embodiment of FIG. 5, there is no opening provided in the insulating substrate layer 25″. As a result, the Silicon base layer 24″ and the SOI layer 26″ are not in electrical contact. Without further measures, the sharp edge 62″ of the contacting structure 60″ may need to engage with a lateral surface portion of the SOI layer 26″ in order to establish electrical contact between the electrically conductive layer 38″ and the contacting structure 60″.

FIG. 6 shows an embodiment of a semiconductor target 10′″ comprising a cover layer 36′″ (e.g. a layer of electrically insulating material) with a peripheral cover portion 37′″ that laterally extends beyond device periphery 35′″ of the device layer 34′″. The peripheral cover portion 37′″ is laterally bounded by structure layer periphery 32′″, and leaves open a contacting portion 23′″ of the substrate 12′. The peripheral cover portion 37′ may for example be formed by a preparation step comprising spin coating of the cover material onto the device layer 34′ and the (still exposed) peripheral substrate region 22′, followed by a preparation step involving sufficient edge bead removal of the cover material from a periphery of the cover layer 36′″, so that the contacting portion 23′ becomes exposed. Similar as in the abovementioned embodiments, a subsequent application of the charge conduction layer 38′″ onto the cover layer 36′″ and the (exposed) contacting portion 23′″ yields an electrically conducting connection between the electrically conductive layer 38′″ and the semiconductor substrate 12′″. In a further preparation step, a layer of resist 42′ is applied on top of the electrically conductive layer 38′.

Again, a radial-axial cross-section of the lateral substrate surface 18′ shows a curved and radially directed U-shape. In the embodiment shown in FIG. 6, the conductive layer 38′″ laterally extends with a peripheral conduction portion 40′ beyond the main substrate surface 14′″ and towards the lateral substrate surface 18′″. The peripheral conduction portion 40′″ at least partially covers the lateral substrate surface 18′″, so that electrical contact with the substrate 12′ is also established in this lateral region. Both the peripheral cover portion 37′ and the peripheral conduction portion 40′″ define smooth contours that curve downward towards the main substrate surface 14′″, as viewed along the direction of increasing radius.

The contacting structure 60′″ depicted in FIG. 6 comprises a cutting edge 62′″ that linearly extends along the axial direction Z. As a result, the cutting edge 62′″ is adapted to engage with the lateral substrate surface 18′″ along a predominantly vertical line.

The descriptions above are intended to be illustrative, not limiting. It will be apparent to the person skilled in the art that alternative and equivalent embodiments of the invention can be conceived and reduced to practice, without departing from the scope of the claims set out below. For example, the features of the various semiconductor target embodiments and lithography system embodiments may be combined to form further embodiments that benefit from any of the corresponding effects related to these features.

Note that for reasons of legibility, the reference numbers corresponding to similar elements in the various embodiments have been collectively indicated in the claims by their base numbers only. However, this does not suggest that the claim elements should be construed as referring only to described features corresponding to base numbers. Although the various similarity indicators for the reference numbers (e.g. 10′, 10″, 10*) have been omitted in the claims, their applicability will be apparent from a comparison with the figures.

### REFERENCE SIGNS LIST

10 semiconductor target
12 semiconductor substrate
14 main substrate surface (upper substrate surface)
16 opposite substrate surface (lower substrate surface)
18 lateral substrate surface
20 substrate periphery
22 peripheral substrate region
23 contacting portion
24 silicon base layer
25 insulating substrate layer
26 silicon on insulator (SOI) layer
27 opening (aperture)
30 structure layer
32 structure layer periphery
34 device layer
35 device layer periphery
36 cover layer (insulating/resistive layer)
37 peripheral cover portion
38 electrically conductive layer (hard mask)
39 electric current
40 peripheral conduction portion
41 electrical conduction path
42 resist layer
43 main target surface (upper target surface)
50 lithography system
52 charged particle projector
54 charged particle beam
56 receptor
58 target support region
59 support protrusion
60 contacting structure
61 top surface
62 cutting edge
65 charge dissipation path
d1 conductive layer thickness
d2 contacting portion width
d3 peripheral substrate region width
Z axial direction (vertical direction)
R radial direction (first lateral direction)
Φ angular direction (second lateral direction)

1. A method for preparing a semiconductor target (10), the method comprising:
providing a semiconductor substrate (12) including:
a main substrate surface (14) which defines a substrate periphery (20) along an outer edge; and
a structure layer (30) arranged on the main substrate surface, and having a structure layer periphery (32) that is located inwards with respect to the substrate periphery, so as to define a peripheral substrate region (22) along the substrate periphery which is not covered by the structure layer;
wherein the method comprises:
applying an electrically conductive layer (38) onto the semiconductor substrate, including and beyond the structure layer, wherein the electrically conductive layer extends beyond the structure layer periphery to establish electrical contact with a contacting portion (23) of the peripheral substrate region.

2. Method according to claim 1, wherein the semiconductor substrate (12) comprises a lateral substrate surface (18) which borders on the main substrate surface (14) and which delineates the substrate periphery (20), and wherein applying the electrically conductive layer (38) on the semiconductor substrate and the structure layer comprises:
extending the electrically conductive layer (38) towards the lateral substrate surface (18) to form an electrical contact with at least a portion of the lateral substrate surface.

3. Method according to claim 1 or 2, wherein the structure layer (30) comprises a cover layer (36), and wherein applying the electrically conductive layer (38) on the semiconductor substrate (12) and the structure layer comprises:
applying the electrically conductive layer directly onto the cover layer (36).

4. Method according to any one of the claims 1-3, wherein the electrically conductive layer (38) is applied for establishing an electrically conductive path through the conductive layer (38) and towards the substrate periphery (20), allowing a net electrical charge, when received by the substrate surface during a charged particle beam process, to be laterally conveyed towards the outer edge of the semiconductor substrate (12) for dissipation of the net electrical charge to a remote drain via a contacting structure (60) external to the semiconductor target (10).

5. Semiconductor target (10), comprising:
a semiconductor substrate (12), including a main substrate surface (14) which defines a substrate periphery (20) along an outer edge;
a structure layer (30) arranged on the main substrate surface, and comprising a structure layer periphery (32) that is located inwards with respect to the substrate periphery so as to define a peripheral substrate region (22) along the substrate periphery which is not covered by the structure layer;
wherein the semiconductor target comprises:
an electrically conductive layer (38) formed on the structure layer, and extending beyond the structure layer periphery to establish electrical contact with a contacting portion (23) of the peripheral substrate region.

6. Semiconductor target (10) according to claim 5, wherein the semiconductor substrate (12) comprises a lateral substrate surface (18) which borders on the main substrate surface (14) and which delineates the substrate periphery (20), wherein the electrically conductive layer (38) extends towards the lateral substrate surface (18) and forms an electrical contact with at least a portion of the lateral substrate surface.

7. Semiconductor target (10) according to claim 5 or 6, wherein the semiconductor substrate (12) comprises a silicon base layer (24), an insulating substrate layer (25) arranged on the silicon base layer, and a SOI layer (26) arranged on the insulating substrate layer.

8. Semiconductor target (10) according to claim 7, wherein the insulating substrate layer (25) includes an aperture (27) having an electrically conductive material therein adapted for establishing electrical contact between the silicon base layer (24) and the SOI layer (26).

9. Semiconductor target (10) according to any one of claims 5-8, wherein the structure layer (30) comprises one or more device layers (34).

10. Semiconductor target (10) according to any one of claims 5-9, wherein the structure layer (30) comprises a cover layer (36), and wherein the electrically conductive layer (38) is arranged directly on top of the cover layer (36).

11. Semiconductor target (10) according to any one of claims 5-10, wherein a resist layer (42) is arranged directly on top of the electrically conductive layer (38).

12. Semiconductor target (10) according to any one of claims 5-11, wherein a width (d2) of the contacting portion (23) is larger than a thickness (d1) of the electrically conductive layer (38), preferably a factor of 10⁵ to 10⁶ times larger.

13. Semiconductor target (10) according to any one of claims 5-12, wherein the electrically conductive layer (38) has an electrical sheet resistance below 10⁵ Ohms per square.

14. Semiconductor target (10) according to any one of the claims 5-13, wherein the electrically conductive layer (38) is formed for establishing an electrically conductive path through the conductive layer (38) and towards the substrate periphery (20), allowing a net electrical charge, when received by the substrate surface during a charged particle beam process, to be laterally conveyed towards the outer edge of the semiconductor substrate (12) for dissipation of the net electrical charge to a remote drain via a contacting structure (60) external to the semiconductor target (10).

15. Lithography system (50) for processing a semiconductor target (10) using a charged particle beam (54), wherein the lithography system comprises:
a charged particle projector (52) for projecting the charged particle beam towards a main target surface (43) of the semiconductor target;
a receptor (56) including a target support region (58) for supporting the semiconductor target during processing, and
a contacting structure (60) provided at a periphery of the target support region and comprising a cutting edge (62) adapted for engaging with a lateral surface (18) of the semiconductor target, wherein the cutting edge comprises an electrically conductive material and is adapted for establishing electrical contact with the lateral surface of the semiconductor target.

16. Lithography system (50) according to claim 15, wherein the semiconductor target (10) is a semiconductor target according to any one of the claims 5-14.
